(19) United States
(12) Patent Application Publication
(10) Pub. No.: US 2011/0299252 A1
(43) Pub. Date: Dec. 8, 2011

(54) EXPANSION CARD ASSEMBLY AND HEAT SINK THEREOF

(75) Inventor: ZEU-CHIA TAN, Tu-Cheng (TW)

(73) Assignee: HON HAI PRECISION INDUSTRY CO., LTD., Tu-Cheng (TW)

(21) Appl. No.: 12/882,217

(22) Filed: Sep. 15, 2010

(30) Foreign Application Priority Data
Jun. 7, 2010 (TW) 99118420

(51) Int. Cl. H05K 7/20; F28F 7/00

(52) U.S. Cl. 361/720; 165/185

(57) ABSTRACT

An expansion card assembly includes an expansion card and a heat sink. The expansion card includes a board and an electronic component mounted on the board. The board has a component side on which the electronic component is mounted and an opposite solder side. The heat sink includes a U-shaped base. The base includes a heat absorbing plate, an opposite heat dissipation plate and a middle connecting plate. An end of the board adjacent to the electronic component is received in a receiving space of the base defined between the heat absorbing plate and the heat dissipation plate. The heat absorbing plate and the heat dissipation plate of the base are respectively located the component side and the solder side of the board to sandwich the end of the board therebetween. The heat absorbing plate is attached to the electronic component.

### BACKGROUND

1. Technical Field

The disclosure generally relates to heat sinks; and more particularly to a heat sink for an expansion card.

2. Description of Related Art

Expansion cards, such as a sound card, a network card or a graphics card, generally includes a board and a plurality of electronic components mounted on the board.

In operation of an expansion card, the electronic components generate heat. In order to remove the heat and hence ensure normal operation, a heat sink is usually provided. The heat sink includes a rectangular base and a plurality of fins formed on the base. The heat sink may for example be attached to one major heat-generating electronic component on the expansion card. Heat generated by the electronic component is transferred to the base and then dissipated by the fins. When the expansion card is used in a thin electronic device such as a rack server or a notebook computer, a height of the fins of the heat sink is limited. As a result, the heat sink may not be able to properly satisfy the heat dissipation requirements of the electronic device.

What is needed, therefore, is a means to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead placed upon clearly illustrating the principles of the present embodiments. Moreover, in the drawings, like reference numerals designate corresponding parts throughout the several views.

FIG. 1 is an isometric, assembled view of an expansion card assembly in accordance with a first exemplary embodiment of the present disclosure.

FIG. 2 is an exploded view of the expansion card assembly of FIG. 1.

FIG. 3 is an exploded view of a heat sink of an expansion card assembly in accordance with a second exemplary embodiment of the present disclosure.

### DETAILED DESCRIPTION

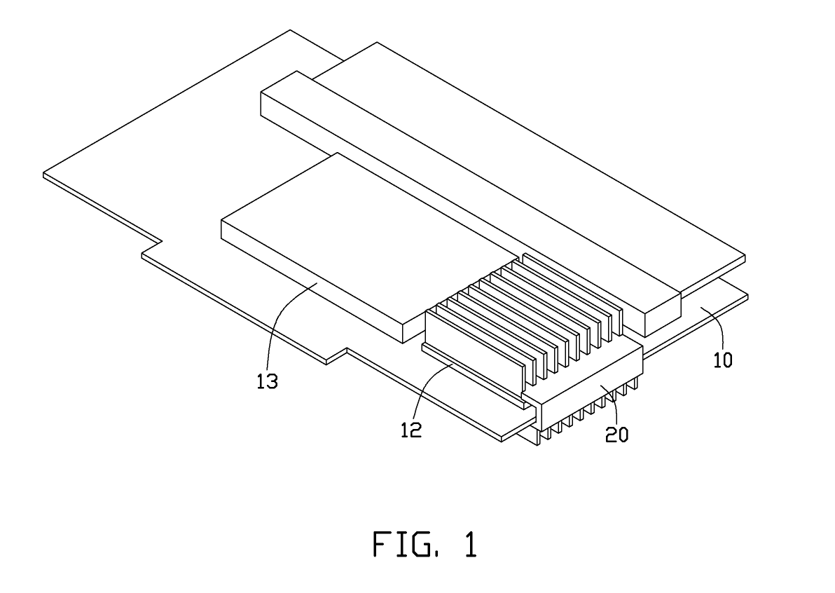

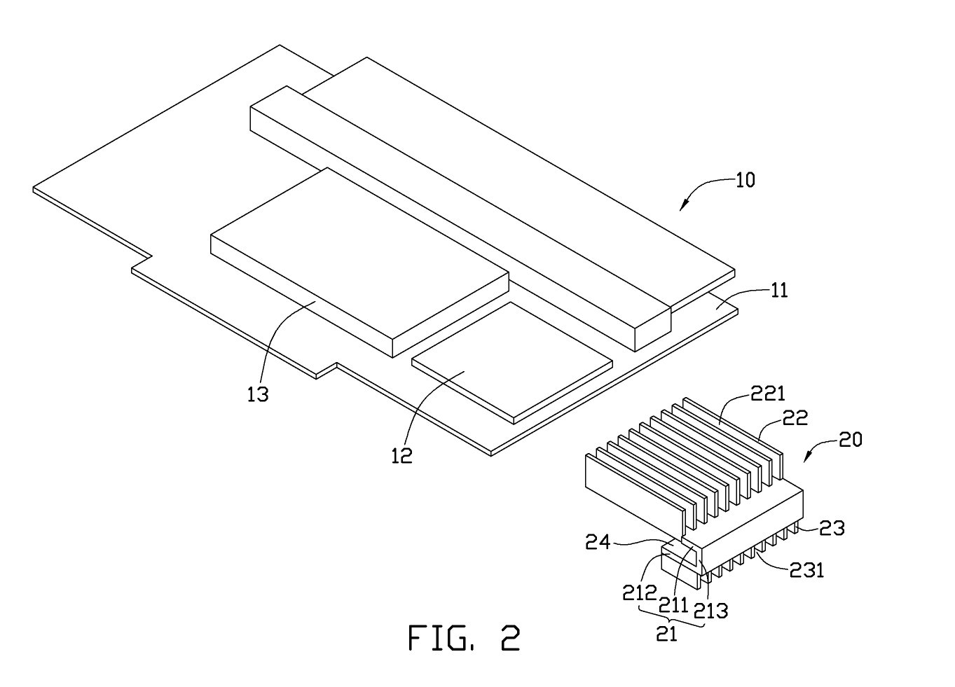

Referring to FIGS. 1-2, an expansion card assembly according to an exemplary embodiment of the present disclosure is shown. The expansion card assembly includes an expansion card 10, and a heat sink 20 mounted on the expansion card 10 for dissipating heat of the expansion card 10.

The expansion card 10 includes a board 11, and two electronic components 12, 13 mounted on one side of the board 11. The board 11 has a top component side on which the electronic components 12, 13 are mounted, and a bottom solder side on which leads of the electronic components 12, 13 are soldered. In this embodiment, the electronic component 12 is located adjacent to a right end of the board 11.

The heat sink 20 includes a base 21, and a plurality of first fins 22 and a plurality of second fins 23 formed on the base 21. The base 21 is U-shaped, and includes a heat absorbing plate 211, a heat dissipation plate 212, and a connecting plate 213 between the heat absorbing plate 211 and the heat dissipation plate 212. The heat dissipation plate 212 is parallel to and spaced from the heat absorbing plate 211. A receiving space 24 is defined between the heat absorbing plate 211 and the heat dissipation plate 212.

The heat absorbing plate 211 has an inner surface facing the heat dissipation plate 212, and an outer surface. The first fins 22 are formed on the outer surface of the heat absorbing plate 211. The first fins 22 are parallel to and spaced from each other. A first air passage 221 is defined between every two adjacent first fins 22. The heat dissipation plate 212 has an inner surface facing the heat absorbing plate 211, and an outer surface. The second fins 23 are formed on the outer surface of the heat dissipation plate 212. The second fins 23 are parallel to and spaced from each other. A second air passage 231 is defined between every two adjacent second fins 23. An extending direction of each of the first air passages 221 is parallel to that of each of the second air passages 231. In this embodiment, the first fins 22, the second fins 23 and the base 21 are integrally formed as a single piece.

In assembly, the end of the board 11 of the expansion card 10 adjacent to the electronic component 12 is received in the receiving space 24 of the heat sink 20. The heat absorbing plate 211 and the heat dissipation plate 212 of the base 21 of the heat sink 20 are located at two opposite sides of the board 11 of the expansion card 10, to sandwich the end of the board 11 therebetween. The heat dissipation plate 212 is located at the solder side of the board 11 of the expansion card 10. The heat absorbing plate 211 is located at the component side of the board 11 of the expansion card 10, and is attached to the electronic component 12. That is, the heat absorbing plate 211 thermally contacts the electronic component 12.

In the expansion card assembly, the heat dissipation plate 212 of the base 21 of the heat sink 20 extends to the solder side of the board 11. Thereby, the heat dissipation area of the heat sink 20 is increased, and space available at the solder side of the board 11 of the expansion card 10 is efficiently utilized. The second fins 23 formed on the heat dissipation plate 212 further increase the total heat dissipation area of the heat sink 20.

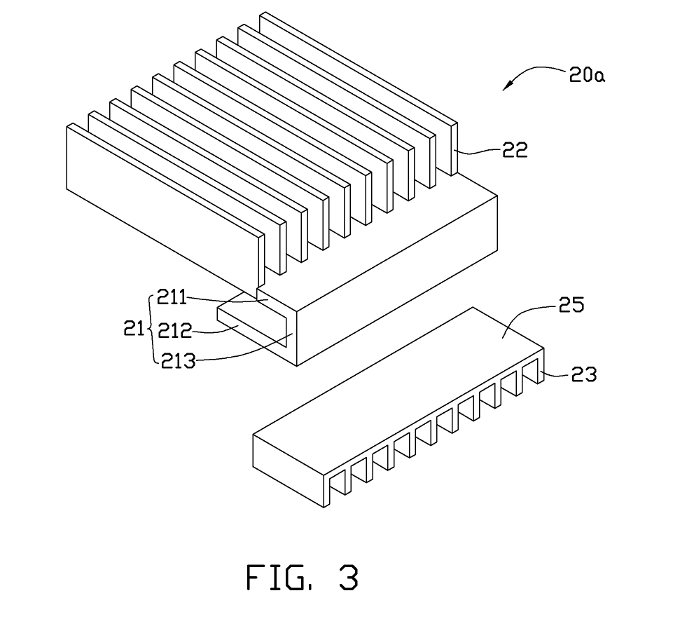

In this embodiment, the second fins 23 are integrally formed with the base 21 as a single piece. That is, the entire heat sink 20 is a single one-piece monolithic body of material. In other embodiments, the second fins 23 and the base 21 can be separately made, and then assembled together. Referring to FIG. 3, this shows a heat sink 20a for the expansion card 10, according to an alternative embodiment. The heat sink 20a includes a base 21 having a heat absorbing plate 211 and a heat dissipation plate 212. A plurality of first fins 22 is integrally formed on the heat absorbing plate 211 of the base 21. That is, the base 21 and the first fins 22 are portions of a single one-piece monolithic body of material. A plurality of second fins 23 are integrally formed with a flat plate 25. That is, the flat plate 25 and the second fins 23 are portions of a single one-piece monolithic body of material. The flat plate 25 is attached to the outer surface of the heat dissipation plate 212 of the base 21 by soldering or by screws.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat sink for dissipating heat of an expansion card, the heat sink comprising:
a U-shaped base comprising:
a heat absorbing plate;
a heat dissipation plate; and
a connecting plate between the heat absorbing plate and the heat dissipation plate, a receiving space being defined between the heat absorbing plate and the heat dissipation plate for receiving the expansion card therein, an inner surface of the heat absorbing plate being configured for thermally contacting an electronic component mounted on the expansion card.

2. The heat sink of claim 1, further comprising a plurality of first fins formed on an outer surface of the heat absorbing plate and spaced from each other.

3. The heat sink of claim 2, further comprising a plurality of second fins, wherein the heat dissipation plate has inner surface facing the heat absorbing plate and an opposite outer surface, the second fins being formed on the outer surface of the heat dissipation plate and spaced from each other.

4. The heat sink of claim 3, wherein a first air passage is defined between every two adjacent first fins, and a second air passage is defined between every two adjacent second fins, an extending direction of the second air passage being parallel to that of the first air passage.

5. The heat sink of claim 4, wherein the extending direction of the first air passage is perpendicular to the connecting plate.

6. The heat sink of claim 3, wherein the first fins, the second fins and the base are integrally formed as a single piece.

7. The heat sink of claim 3, wherein the second fins are integrally formed on a flat plate, and the flat plate is attached to the outer surface of the heat dissipation plate of the base.

8. An expansion card assembly comprising:
an expansion card comprising a board and an electronic component mounted on the board, the board having a component side and an opposite solder side, the electronic component being mounted on the component side and located adjacent to an end of the board; and
a heat sink for dissipating heat of an expansion card, the heat sink comprising:
a U-shaped base comprising:
a heat absorbing plate;
a heat dissipation plate opposite to the heat absorbing plate; and
a connecting plate between the heat absorbing plate and the heat dissipation plate, a receiving space being defined between the heat absorbing plate and the heat dissipation plate, the end of the board of the expansion card adjacent to the electronic component received in the receiving space of the base, the heat absorbing plate and the heat dissipation plate of the base of the heat sink being respectively located at the component side and the solder side of the board of the expansion card to sandwich the end of the board therebetween, the heat absorbing plate being attached to the electronic component.

9. The expansion card assembly of claim 8, wherein the heat sink further comprises a plurality of first fins, the heat absorbing plate having an outer surface opposite to the inner surface thereof, the first fins being formed on the outer surface of the heat absorbing plate and spaced from each other.

10. The expansion card assembly of claim 9, wherein the heat sink further comprises a plurality of second fins, the heat dissipation plate having inner surface facing the heat absorbing plate and an opposite outer surface, the second fins being formed on the outer surface of the heat dissipation plate and spaced from each other.

11. The expansion card assembly of claim 10, wherein a first air passage is defined between every two adjacent first fins, and a second air passage is defined between every two adjacent second fins, an extending direction of the second air passage being parallel to that of the first air passage.

12. The expansion card assembly of claim 11, wherein the extending direction of the first air passage is perpendicular to the connecting plate.

13. The expansion card assembly of claim 10, wherein the first fins, the second fins and the base are integrally formed as a single piece.

14. The expansion card assembly of claim 10, wherein the second fins are integrally formed on a flat plate, and the flat plate is attached to the outer surface of the heat dissipation plate of the base.

15. A heat sink for dissipating heat of an expansion card, the heat sink comprising:
a U-shaped base comprising:
a heat absorbing plate;
a heat dissipation plate substantially parallel to the heat absorbing plate; and
a connecting plate between the heat absorbing plate and the heat dissipation plate, a receiving space being defined between the heat absorbing plate and the heat dissipation plate, the receiving space sized to fittingly receive an end of the expansion card therein such that an inner surface of the heat absorbing plate thermally contacts an electronic component mounted on the expansion card.
